(19) United States
(12) Patent Application Publication
(10) Pub. No.: US 2003/0122261 A1
(43) Pub. Date: Jul. 3, 2003

(54) Power semiconductor submodule, and a power semiconductor module

(76) Inventors: Bo Bijlenga, Amal (SE); Fabian Zwick, Suhr (CH); Amina Hamidi, Baden (CH); Luc Meysenc, Baden-Dattwil (CH); Stefan Kaufmann, Aarau (CH); Patrick Erne, Elsau (CH)

Correspondence Address: BURNS, DOANE, SWECKER & MATHIS, L.L.P., P. O. Box 1404, Alexandria, VA, 22313-1404, US

(21) Appl. No.: 10/306,412

(22) Filed: Nov. 29, 2002

(30) Foreign Application Priority Data
Dec. 6, 2001 (EP) 01811189.8

(51) Int. Cl. H01L 23/48

(52) U.S. Cl. 257/777

(57) ABSTRACT

The power semiconductor submodule (1) has at least two semiconductor chips (21, 22), which have two main electrodes (3, 4), between two main connections (6, 7), with a contact force being exerted by a contact die (8) on the one main electrode (3), and the other main electrode (4) of the semiconductor chip (21, 22) thus being pressed against a base plate (5). The two semiconductor chips (21, 22) are electrically connected in series between the two main connections (6, 7) of the power semiconductor submodule.

Since, like conventional press pack modules, the two semiconductor chips are arranged alongside one another on the base plate, the physical height of the power semiconductor submodule according to the invention is not increased. On the other hand, the electrical series connection increases the maximum blocking voltage of the power semiconductor submodule.

### DESCRIPTION

1. Technical Field

The invention relates to the field of power electronics. It relates in particular to a power semiconductor submodule as claimed in the precharacterizing clause of patent claim 1, and to a power semiconductor module.

2. Prior art

For high-power applications, power semiconductor modules are manufactured using press pack module technology. These press pack modules are used as high-power switches for currents of up to several thousand amperes in the high-voltage range up to 1000 kV. Since insulated gate bipolar transistors (IGBT), as are used nowadays in a press pack module, can withstand a voltage of only around a few thousand volts, a number of press pack modules are connected in series in at least one stack for a high-voltage switch. The stack, with up to several dozen press pack modules, is compressed with a force of around 100 kN.

A press pack module, such as that described in EP 762,496, generally has a number of semiconductor chips which are arranged alongside one another and are mounted with their first main electrode on a base plate. The second main electrodes of the semiconductor chips are made contact with by a number of contact dies. The base plate is connected to a first main connection, and the contact dies are connected to a second main connection. The main connections may be in the form of disks, and may be interconnected by means of flanges. The pressure contact is thus in the form of a copper die, which presses against the individual chips.

The individual semiconductor chips in the press pack module are nowadays formed into several groups and are combined in units, “submodule”, which can be prefabricated. In this case, the semiconductor chips are connected in parallel with one another, for example with a number of IGBTs and diode chips together in one submodule.

A stack with press pack modules extends over a length of several meters. Complex precautions are necessary in order to allow the pressure mentioned above to be exerted over such a length. It is thus desirable to increase the maximum blocking voltage per unit length in a stack, in order to manage with fewer press pack modules for a given voltage.

The height of the stack, and hence the costs associated with it, could be reduced by increasing the blocking voltage of individual press pack modules. Unfortunately there is scarcely any prospect of raising the maximum blocking voltage, as mentioned above, of power semiconductor chips with present-day technology.

### BRIEF DESCRIPTIONS OF THE INVENTION

The object of the present invention is thus to provide a power semiconductor submodule and a power semiconductor module of the type mentioned above, which have a higher blocking voltage while their physical height is essentially the same.

According to the invention, this object is achieved by a power semiconductor submodule with the features of patent claim 1, and by a power semiconductor module with the features of patent claim 13.

The power semiconductor submodule according to the invention has at least two semiconductor chips, which have two main electrodes, between two main connections, with a contact force being exerted by a contact die on the one main electrode, and the other main electrode of the semiconductor chip thus being pressed against a base plate. The two semiconductor chips are electrically connected in series between the two main connections of the power semiconductor submodule.

Since, like conventional press pack modules, the two semiconductor chips are arranged alongside one another on the base plate, the physical height of the power semiconductor submodule according to the invention is not increased. On the other hand, the electrical series connection increases the maximum blocking voltage of the power semiconductor submodule.

In a first embodiment, insulation layers are arranged between the one semiconductor chip and the base plate, as well as between the other semiconductor chip and the corresponding contact die. The two semiconductor chips are electrically conductively connected to a connecting lead at the electrodes that are insulated in this way.

This results in a simple series circuit, with the current flowing from one main connection via a first contact die and the one semiconductor chip through the connecting lead and the other semiconductor chip to the base plate, and to the other main connection which is connected to it.

In a first advantageous variant of the first embodiment, the connecting lead has two electrically conductive plates, which are electrically connected via a connection layer which is located between them.

The two plates are essentially flat. The height difference between the two plates, caused by the main electrodes of the two semiconductor chips being at different levels, is bridged by the electrically conductive connection layer.

In a second advantageous variant of the first embodiment, the base plate is thicker in the region of the semiconductor chip which is isolated from the base plate, so that the main electrodes (which are connected via the connecting lead) of the two semiconductor chips essentially lie in a plane.

The connecting lead may thus once again be essentially flat.

In a second embodiment, the one insulation layer between the one semiconductor chip and the base plate is lengthened to the other semiconductor chip, which is thus likewise isolated from the base plate. In addition, this semiconductor chip is arranged reversed in comparison to the first embodiment (flip chip), so that the connecting lead which is arranged on the insulation layer connects the series-connected electrodes of the two semiconductor chips. A further connecting lead leads to the base plate from the second electrode, which is isolated from the corresponding contact die by an insulation layer, of the semiconductor chip which is arranged reversed.

Copper bonding connections may be used, by way of example, as connecting leads. These are easy to fit and are readily available. Furthermore, metal wire meshes, metal wires or metal foils may be used, in particular for heavy currents of more than 1000 amperes.

In a third embodiment, an electrically insulating layer is once again arranged between the one main electrode of the one semiconductor chip and the base plate. Furthermore, a second electrically insulating layer is once again arranged between the one main connection and the contact die which makes contact with the one main electrode of the other semiconductor chip. The one insulated electrode of the one semiconductor is once again connected to the insulated contact die of the other semiconductor via a connecting lead.

In one advantageous variant of the third embodiment, the connecting lead has two electrically conductive plates, which are arranged between the main electrode and the insulation layer, and/or between the contact die and the insulation layer, and an additional contact die, which electrically conductively connects the two plates.

The connecting lead is manufactured only from robust metal parts. The series connection is made possible by means of simple, straight metal and insulation parts. This results in advantages during assembly.

Simple circuits, for example a parallel circuit formed from IGBTs with two series-connected diodes, can be used in the power semiconductor submodule according to the invention and/or in the power semiconductor module according to the invention.

Further exemplary embodiments can be found in the corresponding dependent claims.

### BRIEF DESCRIPTION OF THE DRAWINGS

The invention will be explained in more detail in the following text with reference to exemplary embodiments and in conjunction with the drawings, in which:

FIG. 1 shows a section through a first embodiment of a power semiconductor submodule according to the invention,

FIG. 2 shows a first advantageous variant of the power semiconductor submodule as shown in FIG. 1,

FIG. 3 shows a second advantageous variant of the power semiconductor submodule as shown in FIG. 1,

FIG. 4 shows a section through a second embodiment of a power semiconductor submodule according to the invention,

FIG. 5 shows a section through a first variant of a third embodiment of the power semiconductor submodule according to the invention,

FIG. 6 shows a section through a second variant of a third embodiment of the power semiconductor submodule according to the invention, and

FIG. 7 shows a section through a power semiconductor module according to the invention.

The reference symbols used in the drawings, and their meanings, are listed in summary form in the list of reference symbols. In principle, identical parts are provided with the same reference symbols in the figures.

Approach to Implementation of the Invention

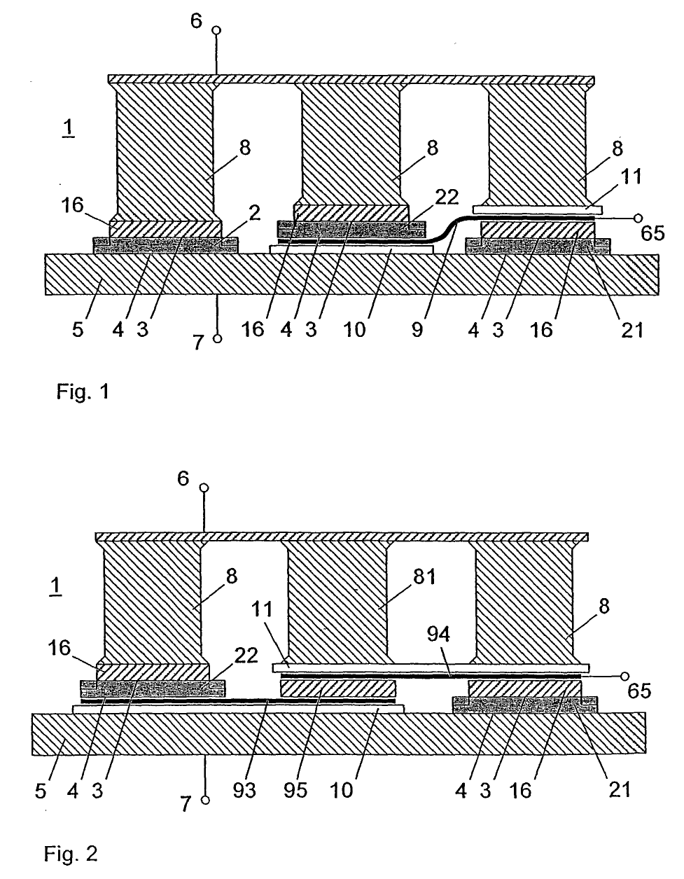

FIG. 1 shows a first embodiment of the power semiconductor submodule according to the invention. 1 denotes the power semiconductor submodule, which has a first and a second main connection, 7 and 6. The main connections 6, 7 are illustrated only symbolically in the drawings, and the second main connection is indicated at least in the form of a conductive plate. It may, by way of example, consist of a solid copper block. A base plate 5 is connected to the first main connection 7. The base plate may, by way of example, be a molybdenum plate or a plate composed of other suitable materials, which is mounted on the first main connection by means of a solder layer. The base plate may have a round or polygonal outline.

A number of semiconductor chips, generally at least two semiconductor chips, are soldered to the base plate 5. The semiconductor chips are preferably IGBT chips or diode chips, or a combination of these types of chips. In principle, however, the chips have at least two main electrodes 3 and 4, which make contact with the corresponding main connections 6 and 7, for example. In the case of IGBT chips, there is also a third electrode, a control electrode, which is connected to a control connection via a connecting wire (which is not illustrated). The connecting wire is in this case bonded, for example, to the control electrode of the corresponding chip. The semiconductor chips are part of a stack comprising a number of layers, for example solder layers or layers in order to improve the short-circuit response (short circuit failure mode, SCFM), as described in detail in EP 989 611. The figures in each case show, symbolically, only the semiconductor chip and one SCFM layer 16, arranged immediately above it.

In the illustrated example, the power semiconductor module 1 has three semiconductor chips, an IGBT 2 as well as two series-connected diodes 21 and 22, connected in parallel with it.

The one, first main electrode 4 is formed by the lower face of the chips 2, 21 and 22. The other, second main electrode 3 is formed in a corresponding way by the upper face of the chips.

The first main electrode 4 of the IGBT 2 rests on the base plate 5, and is electrically conductively connected to the first main connection 7 via it. The second main electrode 3 of the IGBT 2 is electrically conductively connected to the second main connection 6 via a contact die 8.

The precise configuration and effect of the contact dies 8 is not of importance to the invention. It can be assumed that the position of the contact dies is individually adjustable corresponding to the distance between the semiconductor chips and a main connection that holds the contact dies. The contact dies may in this case, for example, either have pressure applied to them by means of a spring element, or may be fixed by means of a solder layer.

The first main electrode 4 of the first of the two diodes 21 likewise rests on the base plate 5. The first main electrode 4 of the second diode 22 likewise rests on the base plate 5, but is electrically insulated from the base plate by means of a first electrically insulating layer 10. While the second main electrode 3 of this second diode 22 is electrically conductively connected to the main connection 6 via the contact die 8, a second electrically insulating layer 11 is arranged between the second main electrode 3 of the first diode 21 and the contact die 8 which is located above it. The two electrically insulated main electrodes are now electrically conductively connected to one another via a connecting lead 9. This results in the two diodes 21 and 22 being connected in series between the two main connections 7 and 6. A connection 65 to the connecting lead may be passed out of the housing of the submodule, which is not illustrated, in order to make external contact, in the same way as the control connection of the IGBT.

The connecting lead 9 may, for example, be manufactured from a metal bonding connection or from metal cable, metal wire meshes or metal foils. By way of example, one particularly suitable metal is copper.

FIG. 2 shows a first preferred variant of the first embodiment of the power semiconductor submodule according to the invention. The illustration shows only two series-connected diodes but, of course, further semiconductor chips may be connected in parallel, as in the previous embodiment. Instead of the direct connecting lead, electrically conductive connection plates 93 and 94 are arranged between the first main electrode 4 of the second diode 22 and the first insulating layer 10, as well as between the second main electrode 3 of the first diode 21 and the second insulating layer 11. These connection plates 93 and 94 are arranged essentially parallel to one another, and overlap in a region between the two diodes. In order to electrically conductively connect the two connection plates, a connection layer 95, preferably composed of copper or some other highly conductive material, is arranged between them, in the region of the overlap.

In order to improve the contact between the connection plates 93 and 94 and the connection layer 95, these may either be soldered together, may be connected by means of low temperature bonding (LTB) and/or, as illustrated in FIG. 2, may have an increased contact force applied to them by means of a contact die 81. It is particularly advantageous in this case for the contact dies 8 and 81 all to be of the same length, since this has been found to be advantageous for production and assembly.

Connecting leads with flat straight plates can be produced and installed more easily, and have a lower inductance than a curved, virtually S-shaped connecting lead. Furthermore, flat connecting leads can be electrically insulated more easily than curved ones.

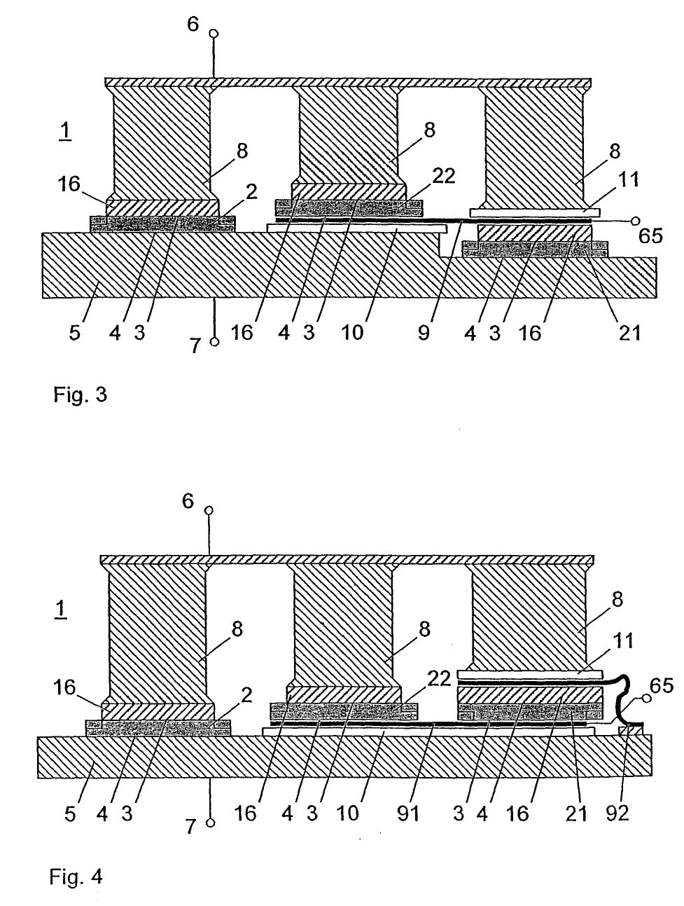

FIG. 3 shows a second preferred variant of the first embodiment of the power semiconductor submodule according to the invention. In contrast to the variant which is illustrated in the first two figures, the base plate 5 is provided with a structure so that the one semiconductor chip, in this case the first diode 21, is located at a different, deeper level than the other semiconductor chip. The base plate is provided with a step, so that the diode which is arranged on the lower step lies in a plane with the upper, second main electrode 3, and with the layers 16 arranged on it, together with the first main electrode 4 of the second diode 22, which rests on the first insulating layer 10.

This allows the two diodes to be connected in series by means of a single straight connecting lead 9.

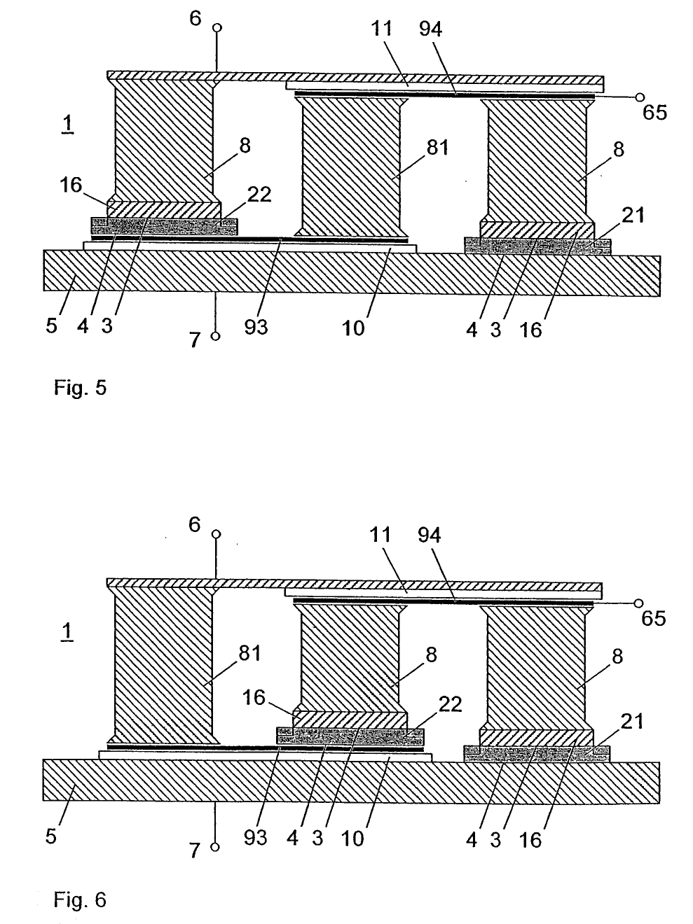

FIG. 4 shows a second embodiment of the power semiconductor submodule according to the invention. Once again, two diodes which are connected in series are connected in parallel with an IGBT 2. The second diode 22 is once again arranged on a first insulating layer 10, although this first insulating layer 10 is now lengthened so that the first diode 21 also rests on it. However, the first diode 21 is reversed with respect to the second diode, that is to say it is inverted (flip chip). The two diodes, to be more precise the second main electrode 3 of the first diode 21 and the first main electrode 4 of the second diode 22, are electrically conductively connected to a first connecting lead 91, which is arranged on the insulating layer 10. A second connecting lead 92 is connected to the base plate from the first main electrode 4 of the first diode 21, which is electrically insulated from the contact die 8 (which is located above it) by means of a second insulating layer 11.

This second connecting lead may, of course, be connected to a further diode or to another semiconductor chip, and may likewise be connected in series with the two diodes.

A third embodiment of the power semiconductor submodule according to the invention is illustrated in FIGS. 5 and 6. This is a simple series circuit formed by two semiconductor chips 21 and 22. Further semiconductor chips may, of course, once again be connected in parallel.

In the same way as in the variant of the first embodiment of the power semiconductor submodule according to the invention as illustrated in FIG. 2, flat, planar connection plates 93 and 93 are used as the connecting lead.

In the first variant illustrated in FIG. 5, the first connection plate 93 is arranged between the first insulating layer 10 and the first main electrode 4 of the second diode 22, and is lengthened at the side into the region between the two diodes. In contrast, as seen from the first diode 21, the second connection plate 94 is arranged after the contact die 8, in the region of the second main connection 6. The second electrically insulating layer 11 is arranged between the second connection plate 94 and the second main connection 6, so that the second connection plate 94 is electrically insulated from the second main connection 6. The second connection plate 94 is likewise lengthened at the side into the region between the two diodes. The two connection plates 93 and 94 are electrically conductively connected by means of a contact die 81.

In the second variant, illustrated in FIG. 6, the two semiconductor chips from FIG. 5 are connected back-to-back in series, which means that the second diode 22 in the series circuit has its polarity reversed. This is achieved by the first main electrode 4 of the second diode 22 likewise resting on the first connection plate 93, but without this first connection plate 93 being lengthened at the side in the direction of the first diode, but in the other direction, and being electrically conductively connected directly to the second main connection 6 via a contact die 81. The second main electrode 3 of the second diode 22 is electrically conductively connected to the second connection plate 94 via a contact die 8.

This embodiment has the advantage that the current-carrying parts are located as far apart from one another as possible. Furthermore, an external contact can be produced easily between the two diodes in the region of the second connection plate 94, which is located at the upper edge of the submodule.

The series connection of a number of semiconductor chips in one submodule makes it possible to provide simple circuits in one submodule, for example a parallel circuit formed by an IGBT with two series-connected diodes. Using conventional submodules, a circuit such as this can be produced only with twice the height.

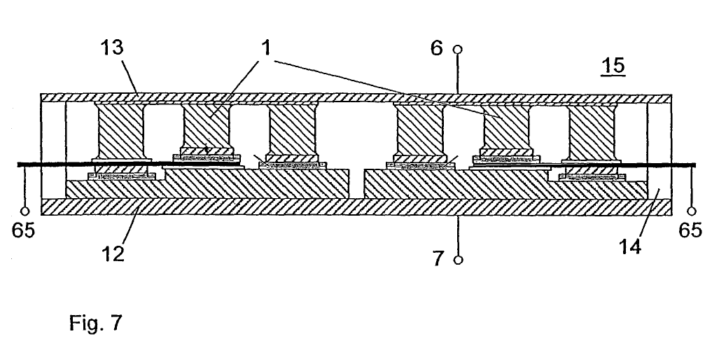

FIG. 7 shows a power semiconductor module according to the invention with three of the power semiconductor submodules described above. The power semiconductor submodules 1 are pressed in between an electrically conductive covering panel 13 and an electrically conductive base plate 12. The covering panel and the base plate are fitted to an electrically insulating housing 14. In particular, the housing bears any excessive contact pressure, so that the semiconductors in the submodules are not excessively loaded by pressure.

The main connections 6 and 7 are connected to the submodules via the covering panel and the base plate. Further connections, for example control connections of IGBTs or a center-point connection 65 of two series-connected diodes, are passed out of the housing of the power semiconductor module at the side.

Modules such as these are especially suitable for applications in a stack. As mentioned, this reduces the height of the stack, thanks to the semiconductor chips in the individual submodules being connected in series.

For the purposes of the invention, the general term the series circuit also covers two components of opposite polarity connected in series (back-to-back series circuit).

### List of Reference Symbols

1 Power semiconductor submodule

2, 21, 22 Semiconductor chips

3, 4 Main electrodes

5 Base plate

6, 7 Main connections

8, 81 Contact die

9, 91, 92, 93, 94, 95 Connecting leads, connection plates

10, 11 Insulating layers

12, 13 Base plate, covering panel

14 Insulating housing

15 Power semiconductor module

16 SCFM layer

65 Connecting lead connection

1. A power semiconductor submodule (1) having
a number of semiconductor chips (2, 21, 22) which have
at least two electrodes, namely a first (4) and a second main electrode (3), which
with a contact force exerted on one of the two main electrodes (3, 4) by a contact die (8) applied to them rest with the other main electrode (4, 3) on a base plate (5), having
a first main connection (7), which
interacts electrically with the base plate (5) and
is electrically connected to a first main electrode (4) of at least one first semiconductor chip (21), and having
a second main connection (6), which
is electrically connected to a second main electrode (3) of at least one second semiconductor chip (22) which rests with the first main electrode (4) on the base plate (5), and
interacts electrically with the corresponding contact die (8),
wherein
the first semiconductor chip (21) and the second semiconductor chip (22) are electrically connected in series between the first main connection (7) and the second main connection (6).

2. The power semiconductor submodule as claimed in claim 1, wherein
a first electrically insulating layer (10) is arranged between the first main electrode (4) of the second semiconductor chip (22) and the base plate (5), in that
a second electrically insulating layer (11) is arranged between the second main electrode (3) of the first semiconductor chip (21) and the corresponding contact die (8), and in that
the first main electrode (4) of the second semiconductor chip (22) and the second main electrode (3) of the first semiconductor chip (21) are electrically conductively connected via a connecting lead (9, 91, . . . , 95).

3. The power semiconductor submodule as claimed in claim 2, wherein
the essentially flat base plate (5) has different thicknesses in the region of the semiconductor chips (21, 22), such that
the first main electrodes (4) of the first and second semiconductor chips lie in separate planes, which are parallel to the base plate (5).

4. The power semiconductor submodule as claimed in claim 2, wherein
the first main electrode (4) of the second semiconductor chip (22) and the second main electrode (3) of the first semiconductor chip (21) essentially lie in a plane which is parallel to the base plate (5), and in that
the connecting lead (9) is essentially flat and runs in this plane.

5. The power semiconductor submodule as claimed in claim 4, wherein
the essentially flat base plate (5) has different thicknesses in the region of the semiconductor chips (21, 22), such that
the first main electrodes (4) of the first and second semiconductor chips lie in separate planes, which are parallel to the base plate (5).

6. The power semiconductor submodule as claimed in claim 1, wherein
the first semiconductor chip (21) rests with the second main electrode (3) on the base plate, in that
a first electrically insulating layer (10) is arranged on the base plate (5), between the first main electrode (4) of the second semiconductor chip (22) and the base plate (5), as well as between the second main electrode (3) of the first semiconductor chip (21) and the base plate (5), in that
a second electrically insulating layer (11) is arranged between the first main electrode (4) of the first semiconductor chip (21) and the corresponding contact die (8), in that
the first main electrode (4) of the second semiconductor chip (22) and the second main electrode (3) of the first semiconductor chip (21) are electrically conductively connected via a first connecting lead (91), and in that
the first main electrode (4) of the first semiconductor chip (21) is electrically conductively connected to the base plate (5) via a second connecting lead (92).

7. The power semiconductor submodule as claimed in claim 2, wherein
the connecting leads (9, 91, 92) comprise copper bonding connections (direct copper bonds) and/or metal cables and/or metal wire meshes and/or metal foils.

8. The power semiconductor submodule as claimed in claim 2, wherein
the connecting lead has
a first electrically conductive connection plate (93), which is arranged between the first main electrode (4) of the second semiconductor chip (22) and the first insulating layer (10),
a second electrically conductive connection plate (94), which is arranged between the second main electrode (3) of the first semiconductor chip (21) and the second insulating layer (11), as well as
a connection layer (95) which electrically conductively connects the first and the second connection plate (93, 94) and is arranged between the first and the second plate (93, 94).

9. The power semiconductor submodule as claimed in claim 8, wherein
the second connection plate (94), the connection layer (95) as well as the first connection plate (94) have a contact force applied to them by means of a contact die (81).

10. The power semiconductor submodule as claimed in claim 1, wherein
a first electrically insulating layer (10) is arranged between the first main electrode (4) of the second semiconductor chip (22) and the base plate (5), in that
a second electrically insulating layer (11) is arranged between the second main connection (6) and the contact die (8) which makes contact with the second main electrode (3) of the first semiconductor chip (21), and in that
the first main electrode (4) or the second main electrode (3) of the second semiconductor chip (22) and the contact die (8) which makes contact with the second main electrode (3) of the first semiconductor chip (21) are electrically conductively connected via a connecting lead (93, 94).

11. The power semiconductor submodule as claimed in claim 10, wherein
the connecting lead has
a first electrically conductive connection plate (93), which is arranged between the first main electrode (4) of the second semiconductor chip (22) and the first insulating layer (10),
a second electrically conductive connection plate (94), which is arranged between the contact die (8), which makes contact with the second main electrode (3) of the first semiconductor chip (21), and the second insulating layer (11), as well as
a contact die (81) which electrically conductively connects the first and the second connection plate (93, 94).

12. The power semiconductor submodule as claimed in claim 10, wherein
a contact die (81) electrically conductively connects a first electrically conductive connection plate (93), which is arranged between the first main electrode (4) of the second semiconductor chip (22) and the first insulating layer (10), to the second main connection (6), and in that
the connecting lead has
a second electrically conductive connection plate (94), which is arranged between the contact die (8), which makes contact with the second main electrode (3) of the first semiconductor chip (21), and the second insulating layer (11), as well as
a contact die (8) which electrically conductively connects the second main electrode (3) of the second semiconductor chip (22) and the second connection plate (94).

13. A power semiconductor module (15) having
an electrically conductive base plate (12) and an electrically conductive covering panel (13), having
a pressure-resistant insulating housing (14) which is arranged between the base plate and the covering panel, and having
one or more power semiconductor submodules, which are arranged alongside one another and/or are connected in parallel, as claimed in one of claims 1 to 12, with
the base plate (12) being electrically conductively connected to the first main connection (6), and
the covering panel (13) being electrically conductively connected to the second main connection (7).
